(19) United States
(12) Patent Application Publication
(10) Pub. No.: US 2006/0134345 A1
(43) Pub. Date: Jun. 22, 2006

(54) Systems and methods for depositing material onto microfeature workpieces

(75) Inventors: Neal R. Rueger, Boise, ID (US); Joel A. Drewes, Boise, ID (US)

Correspondence Address: PERKINS COIE LLP;PATENT-SEA, P.O. BOX 1247, SEATTLE, WA, 98111-1247, US

(73) Assignee: Micron Technology, Inc.

(21) Appl. No.: 11/018,142

(22) Filed: Dec. 20, 2004

(51) Int. Cl. H05H 1/24; C23C 16/00

(52) U.S. Cl. 427/569; 118/719; 118/723 R

(57) ABSTRACT

Systems and methods for depositing materials onto a microfeature workpiece are disclosed herein. In one embodiment, a system includes a first deposition chamber, a gas distributor carried by the first deposition chamber, a second deposition chamber operably coupled to the first deposition chamber, an energy source, and a workpiece support movable between the first and second deposition chambers. The energy source is configured to generate a plasma energy and direct the plasma energy toward a plasma zone in the second deposition chamber. The system may also include a barrier positioned in the second deposition chamber to divide the plasma zone into a first zone and a second zone. The barrier is configured to selectively control the movement of ions from the first zone to the second zone.

### TECHNICAL FIELD

The present invention is related to systems and methods for depositing material onto microfeature workpieces. More particularly, the present invention is directed to systems and methods for plasma vapor deposition.

### BACKGROUND

Thin film deposition techniques are widely used in the manufacturing of microfeatures to form a coating on a workpiece that closely conforms to the surface topography. The size of the individual components in the workpiece is constantly decreasing, and the number of layers in the workpiece is increasing. As a result, both the density of components and the aspect ratios of depressions (i.e., the ratio of the depth to the size of the opening) are increasing. Thin film deposition techniques accordingly strive to produce highly uniform conformal layers that cover the sidewalls, bottoms, and corners in deep depressions that have very small openings.

One widely used thin film deposition technique is Chemical Vapor Deposition (CVD). In a CVD system, one or more precursors capable of reacting to form a solid thin film are mixed while in a gaseous or vaporous state, and then the precursor mixture is presented to the surface of the workpiece. The surface of the workpiece catalyzes the reaction between the precursors to form a solid thin film on the workpiece surface. A common way to catalyze the reaction at the surface of the workpiece is to heat the workpiece to a temperature that causes the reaction. CVD processes are routinely employed in many stages of manufacturing microelectronic components.

Atomic Layer Deposition (ALD) is another thin film deposition technique that is gaining prominence in manufacturing microfeatures on workpieces. FIGS. 1A and 1B schematically illustrate the basic operation of ALD processes. Referring to FIG. 1A, a layer of gas molecules. A coats the surface of a workpiece W. The layer of A molecules is formed by exposing the workpiece W to a precursor gas containing A molecules and then purging the chamber with a purge gas to remove excess A molecules. This process can form a monolayer of A molecules on the surface of the workpiece W because the A molecules at the surface are held in place during the purge cycle by physical adsorption forces at moderate temperatures or chemisorption forces at higher temperatures. Referring to FIG. 1B, the layer of A molecules is then exposed to another precursor gas containing B molecules. The A molecules react with the B molecules to form an extremely thin layer of solid material C on the workpiece W. Such thin layers are referred to herein as nanolayers because they are typically less than 1 nm thick and usually less than 2 Å thick. The chamber is then purged again with a purge gas to remove excess B molecules.

Another type of ALD process is plasma ALD in which energy is added to the gases inside the reaction chamber to form a plasma. FIG. 2 schematically illustrates a conventional plasma processing system 1 including a processing vessel 2 and a microwave transmitting window 4. The plasma processing system 1 further includes a microwave generator 6 having a rectangular wave guide 8 and a disk-shaped antenna 10. The microwaves radiated by the antenna 10 propagate through the window 4 and into the processing vessel 2 to produce a plasma.

A typical plasma ALD cycle includes (a) exposing the workpiece W to the first precursor A, (b) purging excess A molecules from the processing vessel 2, (c) exposing the workpiece W to the second precursor B while generating a plasma in the processing vessel 2 to cause the first and second precursors A and B to react and form a layer of material on the workpiece W, and (d) purging excess B molecules from the processing vessel 2. In actual processing, several cycles are repeated to build a thin film on a workpiece having the desired thickness. For example, each cycle may form a layer having a thickness of approximately 0.5-1.0 Å, and thus several cycles are required to form a solid layer having a thickness of approximately 60 Å.

Energy generators in conventional plasma processing systems include capacitive couplings for storing energy so that the generator can generate plasma in the processing vessel at regular intervals. One drawback of such systems is that the capacitive couplings produce an initial energy spike that causes sputtering and/or degradation at the surface of the workpiece. Moreover, the voltage is high enough to maintain steady-state sputtering. This produces a nonuniform surface across the workpiece and increases the number of deposition cycles required to build up a layer with a desired thickness. Moreover, the molecules that are dislodged from the surface of the workpiece can create particles within the processing chamber that contaminate the workpiece W.

Another drawback of conventional plasma processing systems is that a secondary deposit of material accumulates on the interior surfaces of the walls and the window during processing. Specifically, first precursor molecules may adhere to the walls of the vessel 2 and the window 4, but the purge gas may fail to remove these molecules during purging. As a result, second precursor molecules will react with the remaining first precursor molecules and form a layer on the walls and the window 4. This secondary deposit of material builds up on the walls and the window 4 as successive microfeature workpieces are processed.

One problem with the secondary deposit is that the processing system 1 must be shut down periodically to remove the material from the walls of the vessel 2 and the window 4. The increased maintenance reduces the throughput of the system 1. Another problem is that the secondary deposit of material has a low transmissivity to the microwave energy radiating from the antenna 10. After a period of time, the secondary deposit of material on the window 4 can block the microwave energy from propagating through the window 4 and into the processing vessel 2. The secondary deposit of material is also generally nonuniform across the interior surface of the window 4. Therefore, the secondary deposit of material on the window 4 can prevent the plasma from forming or produce nonuniform films on the workpiece W. Accordingly, there is a need to improve conventional plasma processing systems to address the above-noted problems.

### BRIEF DESCRIPTION OF THE DRAWINGS

FIGS. 1A and 1B are schematic cross-sectional views of stages in ALD processing in accordance with the prior art.

FIG. 2 is a schematic cross-sectional view of a plasma vapor deposition system in accordance with the prior art.

FIG. 3 is a schematic representation of a plasma vapor deposition system for depositing material onto a microfeature workpiece in accordance with one embodiment of the invention.

FIG. 4 is a schematic isometric view of a barrier in the plasma vapor deposition system of FIG. 3.

FIG. 5 is a schematic representation of a plasma vapor deposition system for depositing material onto a microfeature workpiece in accordance with another embodiment of the invention.

FIG. 6 is a schematic representation of a plasma vapor deposition system for depositing material onto a microfeature workpiece in accordance with another embodiment of the invention.

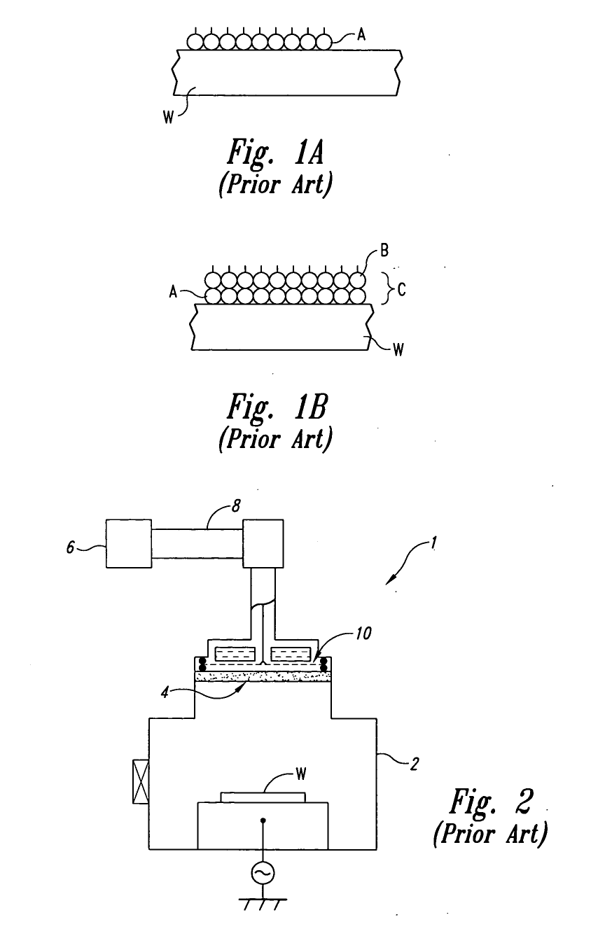

### DETAILED DESCRIPTION

A. Overview

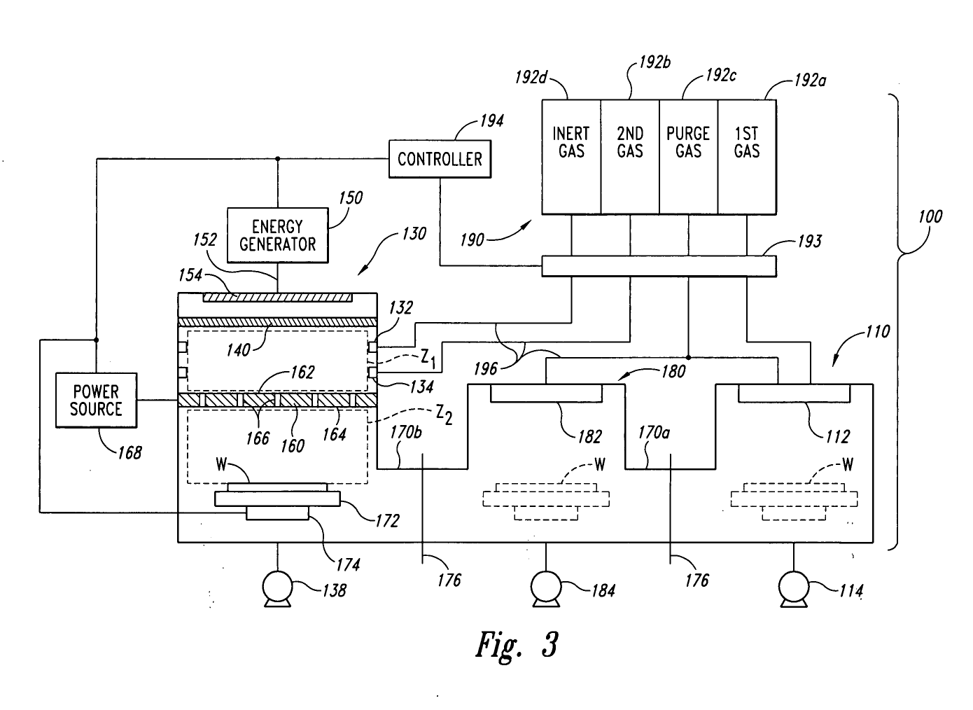

The following disclosure describes several embodiments of plasma vapor deposition systems for depositing materials onto microfeature workpieces, and methods for depositing materials onto workpieces. Many specific details of the invention are described below with reference to single-wafer reaction chambers for depositing materials onto microfeature workpieces, but several embodiments can be used in batch systems for processing a plurality of workpieces simultaneously. The term “microfeature workpiece” is used throughout to include substrates upon which and/or in which microelectronic devices, micromechanical devices, data storage elements, read/write components, and other features are fabricated. For example, microfeature workpieces can be semiconductor wafers such as silicon or gallium arsenide wafers, glass substrates, insulative substrates, and many other types of materials. Furthermore, the term “gas” is used throughout to include any form of matter that has no fixed shape and will conform in volume to the space available, which specifically includes vapors (i.e., a gas having a temperature less than the critical temperature so that it may be liquefied or solidified by compression at a constant temperature). Several embodiments in accordance with the invention are set forth in FIGS. 3-6 and the following text to provide a thorough understanding of particular embodiments of the invention. A person skilled in the art will understand, however, that the invention may have additional embodiments, or that the invention may be practiced without several of the details of the embodiments shown in FIGS. 3-6.

Several aspects of the invention are directed to systems for depositing materials onto a microfeature workpiece. In one embodiment, a system includes a first deposition chamber for depositing molecules of a first gas onto a workpiece, a gas distributor carried by the first deposition chamber, and a second deposition chamber for depositing molecules of a second gas onto the workpiece. The first and second deposition chambers are operably coupled so that the workpiece can move back and forth between the chambers. The system further includes (a) an energy source for generating plasma energy and directing the plasma energy toward a plasma zone in the second deposition chamber, and (b) a barrier positioned in the second deposition chamber for dividing the plasma zone into a first zone and a second zone. The barrier is configured to selectively control the movement of ions from the first zone to the second zone.

In another embodiment, a system includes a first deposition chamber and a second deposition chamber operably coupled to the first deposition chamber. The second deposition chamber includes (a) an energy source for generating a plasma energy and directing the plasma energy toward a plasma zone in the second deposition chamber, (b) a window transmissive of the-plasma energy between the energy source and the plasma zone, and (c) a barrier for selectively controlling the movement of ions from a first zone in the second deposition chamber to a second zone in the second deposition chamber. The system further includes a gas supply assembly having a first gas source in fluid communication with the first deposition chamber and a second gas source in fluid communication with the second deposition chamber. The system also includes a workpiece support movable between the first and second deposition chambers.

Another aspect of the invention is directed to methods for depositing material onto a microfeature workpiece. In one embodiment, a method includes depositing molecules of a first gas onto the microfeature workpiece in a first deposition chamber, generating a steady-state plasma in a second deposition chamber, and depositing molecules of a second gas onto the first gas molecules on the workpiece in the second deposition chamber while generating the steady-state plasma. The method may further include selectively passing at least a portion of the ions in the steady-state plasma toward the microfeature workpiece while depositing molecules of the second gas onto the workpiece.

B. Embodiments of Plasma Vapor Deposition Systems for Fabricating Microfeatures on Workpieces

FIG. 3 is a schematic representation of a plasma vapor deposition system 100 for depositing material onto a microfeature workpiece W in accordance with one embodiment of the invention. The illustrated system 100 includes a first deposition unit with a first chamber 110 for depositing molecules of a first gas onto the workpiece W, a second deposition unit with a second chamber 130 for depositing molecules of a second gas onto the first gas molecules on the workpiece W, and a gas supply 190 for providing the first and second gases to the first and second chambers 110 and 130, respectively. The system 100 further includes an energy generator 150 (shown schematically) for generating a plasma in the second chamber 130 that causes the first and second gas molecules to react and form a layer of material on the workpiece W.

The illustrated first chamber 110 includes a gas distributor 112 coupled to the gas supply 190 for dispensing the first gas into the first chamber 110 and onto the workpiece W when the workpiece W is in the first chamber 110 (shown in broken lines). The gas distributor 112 can be a shower head or other suitable device for depositing first gas molecules uniformly across the surface of the workpiece W. Excess molecules of the first gas are removed from the first chamber 110 with a vacuum pump 114.

The illustrated second chamber 130 includes first and second gas distributors 132 and 134 coupled to the gas supply 190 for dispensing an inert gas and a second gas, respectively, into a first zone Z, of the second chamber 130. The first and second gas distributors 132 and 134 can each include an annular antechamber with a plurality of ports for injecting or flowing the corresponding gas into the second chamber 130. Alternatively, the first and second gas distributors 132 and 134 can be combined into a single manifold having a plurality of different conduits so that individual gases are delivered into the second chamber 130 through dedicated ports.

The second chamber 130 further includes a window 140 transmissive to plasma energy. The window 140 can be a plate or pane of material through which energy propagates into the second chamber 130 to generate a plasma from the inert gas in the first zone Z₁. The window 140 accordingly has a high transmissivity to the plasma energy that generates the plasma. For example, when microwave energy is used to generate the plasma, the window 140 can be a quartz plate or other member that readily transmits microwaves.

The second chamber 130 also includes the energy generator 150 (shown schematically), an energy guide 152 coupled to the energy generator 150, and an antenna 154 or other type of transmitter coupled to the energy guide 152. The energy generator 150 generates a plasma energy that propagates through the energy guide 152 to the antenna 154, and the antenna 154 transmits the plasma energy through the window 140 to the inert gas in the first zone Z₁. The energy generator 150 can generate microwave, radio-frequency, or other suitable types of radiation. For example, the energy generator 150 can produce microwave energy at 2.45 GHz or another frequency suitable for producing a plasma from the inert gas in the first zone Z₁.

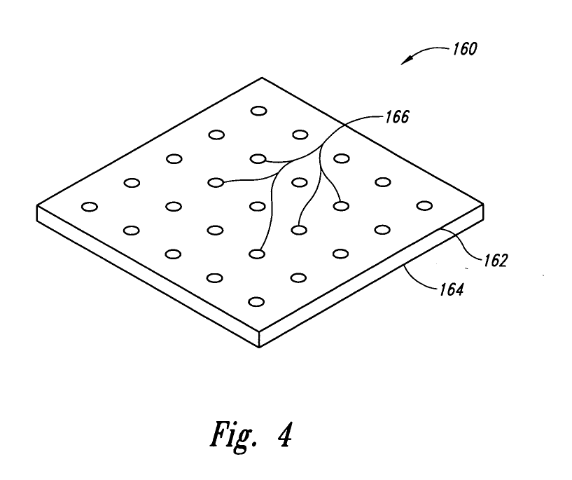

The system 100 of the illustrated embodiment also includes an electrical grid or barrier 160 in the second chamber 130 and a power source 168 (shown schematically) electrically connected to the barrier 160. FIG. 4 is a schematic isometric view of the barrier 160 of FIG. 3. Referring to both FIGS. 3 and 4, the barrier 160 includes a first surface 162 adjacent to the first zone Z. (FIG. 3), a second surface 164 opposite the first surface 162, and a plurality of apertures 166 extending from the first surface 162 to the second surface 164. The apertures 166 are sized and positioned so that a sufficient number of positive ions in the plasma can pass through the barrier 160 as described below. The barrier 160 is made of a conductive material and may have-an insulative coating on the first surface 162 that is inert with respect to the plasma and the second gas. Although the illustrated barrier 160 is a plate, in other embodiments, the barrier 160 can be a screen with apertures or a mesh with another suitable configuration.

Referring only to FIG. 3, the barrier 160 and the power source 168 work together to control the plasma ions within the second chamber 130. For example, when the power source 168 applies a positive charge to the barrier 160, the barrier 160 repels positive ions away from a second zone Z₂ so that the positive ions remain within the first zone Z₁ of the second chamber 130. Alternatively, when the power source 168 applies a negative charge to the barrier 160, the barrier 160 draws positive ions toward the second zone Z₂ such that the momentum of the positive ions carries the ions through the apertures 166 and into the second zone Z₂ of the second chamber 130. The barrier 160 and the power source 168 can accordingly control the movement of the plasma ions within the second chamber 130 to selectively shield the workpiece W from plasma ions or drive the ions toward the workpiece W. In other embodiments, the barrier 160 can be a mechanical barrier that opens and closes to selectively inhibit the ion from moving from the first zone Z₁ to the second zone Z₂.

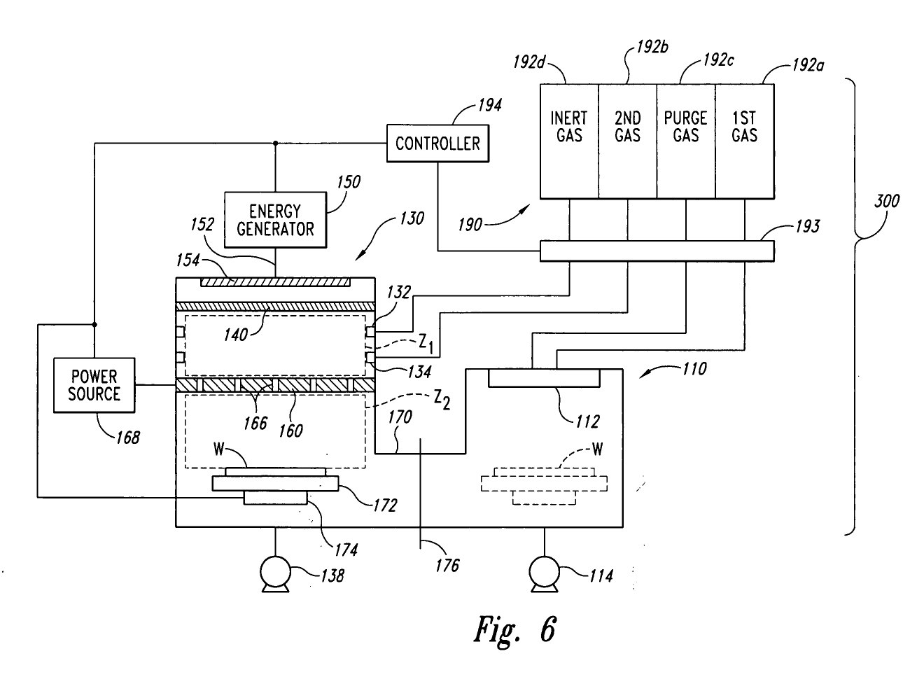

The illustrated system 100 further includes a third chamber 180 between the first and second chambers 110 and 130 to inhibit the first gas from entering the second chamber 130 and the second gas from entering the first chamber 110. The third chamber 180 can include a gas distributor 182 coupled to the gas supply 190 for dispensing the purge gas into the chamber 180 with a positive pressure that exceeds the pressure in the first and second chambers 110 and 130 and inhibits (a) molecules of the first gas in the first chamber 110 from migrating to the second chamber 130, and (b) molecules of the second gas in the second chamber 130 from migrating to the first chamber 110. As a result, the positive pressure in the third chamber 180 prevents contamination of the first and second chambers 110 and 130. Excess gas molecules are removed from the third chamber 180 with a vacuum pump 184. In other embodiments, such as the embodiment described below with reference to FIG. 6, the system 100 may not include the third chamber 180.

In the illustrated embodiment, the system 100 further includes a workpiece support 172 for holding the workpiece W and a positioning device 174 for moving the workpiece support 172 between the first, second, and third chambers 110, 130, and 180. The illustrated system 100 also includes a first passageway 170a or slot between the first and third chambers 110 and 180 and a second passageway 170b or slot between the second and third chambers 130 and 180. The first and second passageways 170a-b are sized such that the workpiece W, the workpiece support 172, and the positioning device 174 can move through the passageways 170a-b between the first and second chambers 110 and 130. The first and second passageways 170a-b can include slit valves 176 to maintain the positive pressure in the third chamber 180 and prevent contamination of the first and second chambers 110 and 130.

The illustrated gas supply 190 includes a plurality of gas sources 192 (shown schematically and identified individually as 192a-d) and a plurality of gas lines 196 coupled to corresponding gas sources 192. The gas sources 192 can include a first gas source 192a for containing the first gas, a second gas source 192b for containing the second gas, a third gas source 192c for containing the purge gas, and a fourth gas source 192d for containing the inert gas. The first and second gases can be first and second precursors, respectively, which are the gas and/or vapor phase constituents that react to form the thin, solid layer on the workpiece W. The purge gas can be a suitable type of gas that is compatible with the first and third chambers 110 and 180 and the workpiece W, and the inert gas can be a suitable type of gas that is compatible with the second chamber 130 and the workpiece W. In other embodiments, the gas supply 190 can include a different number of gas sources 192 for applications that require additional precursors or purge gases.

The system 100 of the illustrated embodiment further includes a valve assembly 193 (shown schematically) coupled to the gas lines 196 and a controller 194 (shown schematically) operably coupled to the valve assembly 193. The controller 194 generates signals to operate the valve assembly 193 and control the flow of the gases into the first, second, and third chambers 110, 130, and 180. The controller 194 can also be operably coupled to (a) the energy generator 150 for controlling the generation of plasma, (b) the power source 168 for controlling the electrical charge of the barrier 160, and (c) the positioning device 174 for controlling the position of the workpiece W.

C. Embodiments of Methods for Depositing Material onto Microfeature Workpieces

FIG. 3 also illustrates an embodiment of a method for depositing material onto the microfeature workpiece W. The controller 194 can contain computer-readable instructions that generate signals for controlling the energy generator 150, the power source 168, the positioning device 174, and/or the valve assembly 193 to deposit layers of material onto the workpiece W. In one method, the positioning device 174 initially positions the workpiece W in the first chamber 110 (shown in broken lines), and then the valve assembly 193 dispenses a pulse of the first gas (e.g., the first precursor) into the first chamber 110 and onto the workpiece W. After depositing a monolayer of first gas molecules on the workpiece W, the valve assembly 193 dispenses a pulse of purge gas into the first chamber 110 to purge excess first gas molecules from the chamber 110. The positioning device 174 then moves the workpiece W from the first chamber 110 to the second chamber 130.

While the workpiece W moves between the first and second chambers 110 and 130, and also while the workpiece W is positioned in the first or second chamber 110 or 130, the valve assembly 193 flows purge gas into the third chamber 180 to inhibit (a) excess first gas molecules from migrating into the second chamber 130, and (b) excess second gas molecules from migrating into the first chamber 110. In other methods, the gas distributor 182 can flow purge gas into the third chamber 180 only when the workpiece W moves between the first and second chambers 110 and 130. Moreover, while the workpiece W moves between the first and second chambers 110 and 130, and while the workpiece W is positioned in the first or second chamber 110 or 130, the valve assembly 193 flows inert gas into the second chamber 130 and the energy generator 150 produces a plasma from the inert gas in the first zone Z₁ of the second chamber 130. Unlike conventional systems, the system 100 generates a steady-state plasma in the first zone Z₁ of the second chamber 130 throughout the processing cycle.

Before the workpiece W is positioned in the second chamber 130, the power source 168 applies a positive charge to the barrier 160 so that the positive ions remain within the first zone Z₁. After the workpiece W is positioned in the second chamber 130, the valve assembly 193 dispenses a pulse of the second gas (e.g., the second precursor) into the first zone Z₁ of the second chamber 130, and a vacuum pump 138 draws the second gas molecules from the first zone Z₁ into the second zone Z₂. Either concurrently with or after dispensing the pulse of second gas into the second chamber 130, the power source 168 reverses the polarity of the barrier 160 so that the positive ions in the plasma pass into the second zone Z₂ with the second gas molecules. In the second zone Z₂, the plasma catalyzes the reaction between the first and second gas molecules at the surface of the workpiece W so that the molecules form a layer of material on the workpiece W. In other embodiments, the second gas distributor 134 can flow the second gas directly into the second zone Z₂, and/or the valve assembly 193 can continuously flow the second gas into the second chamber 130 rather than dispensing a pulse of the second gas.

After the first and second gas molecules react, the vacuum pump 138 draws excess second gas molecules out of the second chamber 130, and the power source 168 reverses the polarity of the barrier 160 so that the positive ions remain within the first zone Z₁. The positioning device 174 subsequently moves the workpiece W back to the first chamber 110, and the process can be repeated for several cycles to form a solid layer having a desired thickness.

One feature of the system 100 illustrated in FIG. 3 is that the energy generator 150 continuously generates plasma at a steady state with a generally constant energy level in the second chamber 130 during processing. An advantage of this feature is that the constant energy level of the plasma reduces or eliminates energy spikes to enable uniform film depositions across the workpiece. Another advantage is that maintaining a steady state plasma reduces ramp times to reduce the time required to build up a layer with a desired thickness. In contrast, the energy generators in conventional plasma processing systems do not generate a steady-state plasma, but rather periodically generate a plasma with a high initial energy that causes sputtering and degradation at the surface of the workpiece and has relatively higher ramp times.

Another feature of the system 100 illustrated in FIG. 3 is that the first chamber 110 deposits the first gas molecules onto the workpiece and the second chamber 130 deposits the second gas molecules onto the workpiece to separate free floating first and second molecules from each other. An advantage of separating free floating first and second gas molecules from each other is that the separation should prevent them from reacting with each other on the interior surfaces of the first and second chambers 110 and 130 or the coupling window 140. This reduces the downtime of the system 100 for cleaning the chambers 110 and 130 and consequently increases the throughput of the system 100. By contrast, in conventional plasma processing systems, the first and second precursors are injected into the same chamber. As such, if the first precursor molecules are not completely purged from the conventional chamber, the first and second precursor molecules will react and accumulate on the interior surface of the walls and window when the second precursor is injected into the chamber. Accordingly, separating the first and second precursors from each other in separate chambers is also expected to produce better film quality because it reduces particulates and non-energy distributions caused by film coatings on the interior surfaces and the window.

D. Additional Embodiments of Plasma Vapor-Deposition Systems

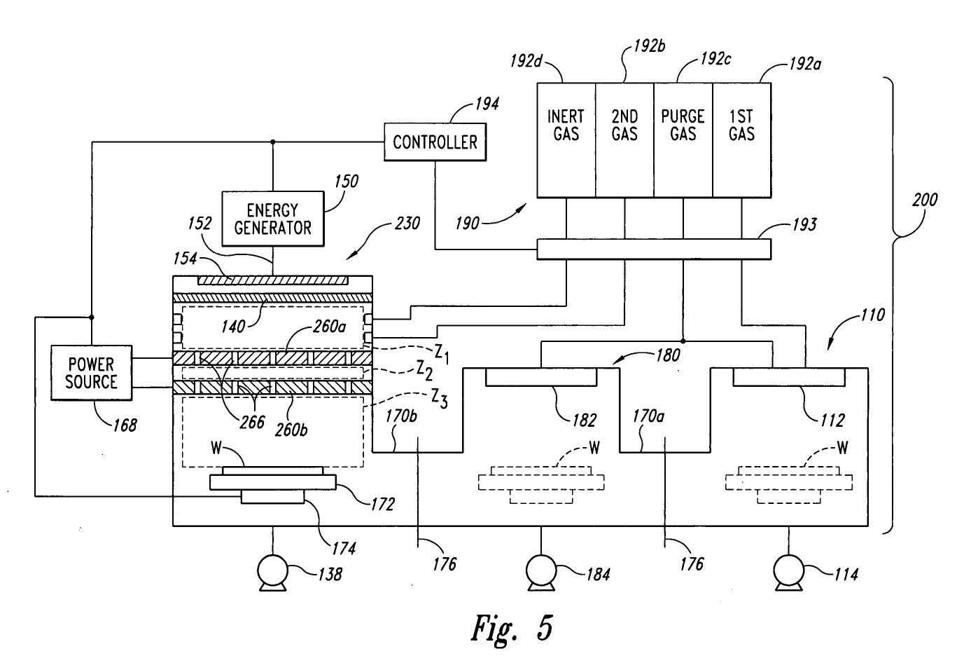

FIG. 5 is a schematic representation of a system 200 for depositing material onto a microfeature workpiece W in accordance with another embodiment of the invention. The illustrated system 200 is generally similar to the system 100 described above with reference to FIG. 3. For example, the illustrated system 200 includes a first chamber 110 for depositing molecules of a first gas onto the workpiece W, a second chamber 230 for depositing molecules of a second gas onto the first gas molecules on the workpiece W, and a gas supply 190 for providing the first and second gases to the first and second chambers 110 and 230, respectively.

The illustrated second chamber 230, however, includes a first electrical barrier 260a and a second electrical barrier 260b spaced apart from the first barrier 260a. The first and second barriers 260a-b are made of a generally conductive material and include a plurality of apertures 266 similar to the barrier 160 described above with reference to FIG. 3. The first and second barriers 260a-b work together to provide enhanced control over the position of the plasma within the second chamber 230. For example, the power source 168 can apply a positive charge to the first barrier 260a to repel positive ions from the first barrier 260a so that the positive ions remain within a first zone Z₁ in the second chamber 230. The power source 168 can also apply a negative charge to the second barrier 260b to repel negative ions from the second barrier 260b so that the negative ions remain within the first zone Z₁ or a second zone Z₂ in the second chamber 230. After the workpiece W is positioned in the second chamber 230, the power supply 164 can reverse the polarity of the first barrier 260a so that the first and second barriers 260a-b are negatively charged and draw the positive ions toward the barriers 260 so that the momentum of the positive ions carries the ions through the apertures 266 in the barriers 260 and into a third zone Z₃ in the second chamber 230. As a result, the first and second barriers 260a-b provide enhanced control over the position and movement of both the positive and negative ions in the plasma during processing.

FIG. 6 is a schematic representation of a system 300 for depositing material onto a microfeature workpiece W in accordance with another embodiment of the invention. The illustrated system 300 is generally similar to the system 100 described above with reference to FIG. 3. For example, the illustrated system 300 includes a first chamber 110 for depositing molecules of a first gas onto the workpiece W, a second chamber 130 for depositing molecules of a second gas onto the first gas molecules on the workpiece W, and a gas supply 190 for providing the first and second gases to the first and second chambers 110 and 130, respectively. The illustrated system 300, however, does not include a third chamber between the first and second chambers 110 and 130. As such, the workpiece W moves directly from the first chamber 110 to the second chamber 130 and directly from the second chamber 130 to the first chamber 110. The slit valve 176 in the passageway 170 between the first and second chambers 110 and 130 inhibits the first gas molecules from migrating into the second chamber 130 and the second gas molecules from migrating into the first chamber 110.

From the foregoing, it will be appreciated that specific embodiments of the invention have been described herein for purposes of illustration, but that various modifications may be made without deviating from the spirit and scope of the invention. For example, either one of the systems 100 and 300 described above with reference to FIGS. 3 and 6, respectively, can include multiple barriers as described above with reference to FIG. 5. Accordingly, the invention is not limited except as by the appended claims.

I/We claim:

1. A system for depositing materials onto a microfeature workpiece, the system comprising:
a first deposition unit having a first deposition chamber and a first gas distributor configured to dispense a first gas into the first deposition chamber;
a second deposition unit having a second deposition chamber, a second gas distributor configured to dispense a second gas into the second deposition chamber, and an energy source configured to generate a plasma energy and direct the plasma energy toward a plasma zone in the second deposition chamber; and
a workpiece support movable between the first and second deposition chambers.

2. The system of claim 1, further comprising a barrier positioned in the second deposition chamber to divide the plasma zone into a first zone and a second zone, the barrier configured to selectively control the movement of ions from the first zone to the second zone.

3. The system of claim 1, further comprising a conductive barrier in the second deposition chamber and a power source coupled to the barrier for electrically charging the barrier.

4. The system of claim 1, further comprising:
a window transmissive of the plasma energy between the energy source and the plasma zone; and
a barrier positioned in the second deposition chamber between the window and the workpiece support when the workpiece support is positioned in the second deposition chamber, the barrier including a plurality of apertures extending through the barrier.

5. The system of claim 1, further comprising a barrier in the second deposition chamber to control the movement of ions in the second deposition chamber, the barrier including a conductive plate with a plurality of apertures.

6. The system of claim 1, further comprising a barrier in the second deposition chamber to control the movement of ions in the second deposition chamber, the barrier including a conductive screen with a plurality of apertures.

7. The system of claim 1, further comprising:
a gas supply assembly for flowing a gas into the plasma zone of the second deposition chamber so that the energy source forms a plasma from the gas; and
a barrier positioned in the second deposition chamber for controlling the position of ions in the second deposition chamber.

8. The system of claim 1, further comprising:
a first conductive barrier in the second deposition chamber;
a second conductive barrier in the second deposition chamber between the first conductive barrier and the workpiece support when the workpiece support is positioned in the second deposition chamber; and
a power source electrically coupled to the first and second conductive barriers for electrically charging the barriers.

9. The system of claim 1, further comprising means for selectively controlling the movement of ions from a first zone of the second deposition chamber to a second zone of the second deposition chamber.

10. The system of claim 1, further comprising a third chamber between the first and second deposition chambers, wherein the workpiece support moves through the third chamber when moving between the first and second deposition chambers.

11. The system of claim 1, further comprising a gas supply assembly having a first gas source in fluid communication with the first deposition chamber and a second gas source in fluid communication with the second deposition chamber.

12. The system of claim 1 wherein the energy source is configured to generate a steady-state plasma energy during normal operation.

13. A system for depositing materials onto a microfeature workpiece, the system comprising:
a first chamber for depositing a layer of first gas molecules onto the microfeature workpiece; and
a deposition unit including (a) a plasma chamber for depositing a layer of second gas molecules onto the layer of first gas molecules, (b) an energy source configured to generate a plasma energy and direct the plasma energy toward a plasma zone in the plasma chamber to catalyze a reaction between the first and second gas molecules on the workpiece, and (c) a window transmissive to the plasma energy, wherein the first chamber and the plasma chamber are configured to transfer the workpiece therebetween.

14. The system of claim 13, further comprising a barrier positioned in the plasma chamber to divide the plasma zone into a first zone and a second zone, the barrier configured to selectively control the movement of ions from the first zone to the second zone.

15. The system of claim 13, further comprising a conductive barrier in the plasma chamber and a power source coupled to the barrier for electrically charging the barrier to control the position of ions in the plasma zone.

16. The system of claim 13, further comprising:
a first conductive barrier in the plasma chamber;
a second conductive barrier in the plasma chamber; and
a power source coupled to the first and second conductive barriers for electrically charging the barriers to control the position of ions in the plasma zone.

17. The system of claim 13, further comprising means for selectively controlling the position of ions in the plasma chamber.

18. The system of claim 13 wherein the energy source is configured to generate a steady-state plasma energy during normal operation.

19. The system of claim 13, further comprising a workpiece support movable between the first chamber and the plasma chamber.

20. A system for depositing materials onto a microfeature workpiece, the system comprising:
a first deposition chamber;
a second deposition chamber operably coupled to the first deposition chamber, the second deposition chamber including (a) an energy source configured to generate a plasma energy and direct the plasma energy toward a first zone in the second deposition chamber, (b) a window between the energy source and the first zone to transmit the plasma energy from the energy source to the first zone, and (c) a barrier configured to selectively control the movement of ions from the first zone to a second zone in the second deposition chamber;
a gas supply assembly having a first gas source in fluid communication with the first deposition chamber and a second gas source in fluid communication with the second deposition chamber; and
a workpiece support movable between the first and second deposition chambers.

21. The system of claim 20 wherein the barrier is an electrically conductive barrier, and wherein the system further comprises a power source coupled to the barrier for electrically charging the barrier.

22. The system of claim 20 wherein the barrier comprises a plate with a plurality of apertures extending through the plate.

23. The system of claim 20 wherein the barrier comprises a first barrier, and wherein the system further comprises a second barrier in the second deposition chamber between the first barrier and the workpiece support when the workpiece support is positioned in the second deposition chamber.

24. The system of claim 20 wherein the energy source is configured to generate a steady-state plasma energy during normal operation.

25. A system for depositing materials onto a microfeature workpiece, the system comprising:
a first deposition chamber;
a second deposition chamber including (a) means for generating a plasma energy and directing the plasma energy toward a first zone in the second deposition chamber, and (b) means for selectively controlling the flow of ions from the first zone to a second zone in the second deposition chamber;
a third chamber between the first and second deposition chambers;
a gas supply assembly having (a) a first gas source in fluid communication with the first deposition chamber, (b) a second gas source in fluid communication with the second deposition chamber, (c) a third gas source in fluid communication with the second deposition chamber, and (d) a fourth gas source in fluid communication with the third deposition chamber; and
means for transferring the microfeature workpiece between the first and second deposition chambers.

26. The system of claim 25 wherein the means for selectively controlling the flow of ions comprises a barrier positioned between the first and second zones.

27. The system of claim 25 wherein the means for selectively controlling the flow of ions comprises an electrical barrier configured to selectively (a) repel the ions so that the ions remain in the first zone, or (b) attract the ions so that at least a portion of the ions move into the second zone.

28. The system of claim 25 wherein the means for selectively controlling the flow of ions comprises a conductive barrier in the second deposition chamber and a power source coupled to the barrier for electrically charging the barrier.

29. The system of claim 25 wherein the means for selectively controlling the flow of ions comprises:
a first barrier in the second deposition chamber; and
a second barrier in the second deposition chamber between the first barrier and the means for transferring the microfeature workpiece between the first and second deposition chambers.

30. The system of claim 25 wherein the means for generating the plasma energy comprises an energy generator configured to generate a steady-state plasma energy during normal operation.

31. A reactor for depositing material onto a microfeature workpiece, the reactor comprising:
a reaction chamber;
a workpiece support in the reaction chamber;
an energy source configured to generate a plasma energy and direct the plasma energy toward a plasma zone in the reaction chamber;
a window transmissive of the plasma energy between the energy source and the plasma zone; and
a barrier in the reaction chamber between the workpiece support and the window, the barrier dividing the plasma zone into a first zone between the window and the barrier and a second zone between the workpiece support and the barrier, the barrier being configured to selectively control the flow of ions from the first zone to the second zone.

32. The reactor of claim 31 wherein the barrier is an electrical barrier configured to selectively (a) repel the ions so that the ions remain in the first zone, or (b) attract the ions so that at least a portion of the ions move into the second zone.

33. The reactor of claim 31, further comprising a power source coupled to the barrier for electrically charging the barrier.

34. The reactor of claim 31 wherein the barrier comprises a conductive plate with a plurality of apertures.

35. The reactor of claim 31 wherein the barrier is a first barrier, and wherein the reactor further comprises a second barrier between the first barrier and the workpiece support.

36. The reactor of claim 31 wherein the energy source is configured to generate a steady-state plasma energy during normal operation.

37. A method for depositing material onto a microfeature workpiece, comprising:
depositing molecules of a first gas onto the microfeature workpiece in a first deposition chamber;
generating a steady-state plasma in a second deposition chamber; and
depositing molecules of a second gas onto the first gas molecules on the workpiece in the second deposition chamber while generating the steady-state plasma.

38. The method of claim 37, further comprising selectively urging at least a portion of the ions in the steady-state plasma toward the microfeature workpiece while depositing molecules of the second gas onto the workpiece.

39. The method of claim 37 wherein generating the steady-state plasma comprises flowing an inert gas into the second deposition chamber and directing plasma energy toward the inert gas, and wherein generating the steady-state plasma occurs while depositing molecules of the first gas onto the workpiece.

40. The method of claim 37, further comprising:
moving the microfeature workpiece from the first deposition chamber to the second deposition chamber after depositing molecules of the first gas onto the workpiece and before depositing molecules of the second gas onto the first gas molecules;
positioning the workpiece in the first deposition chamber after depositing molecules of the second gas onto the first gas molecules; and
depositing molecules of the first gas onto the workpiece after positioning the workpiece in the first deposition chamber.

41. The method of claim 37 wherein generating the steady-state plasma comprises producing the plasma in a first zone of the second deposition chamber, and wherein the method further comprises temporarily inhibiting positive ions in the steady-state plasma from moving from the first zone to a second zone in the second deposition chamber proximate to the workpiece.

42. The method of claim 37 wherein generating the steady-state plasma comprises producing the plasma in a first zone of the second deposition chamber, and wherein the method further comprises:
temporarily inhibiting positive ions in the steady-state plasma from moving from the first zone to a second zone in the second deposition chamber proximate to the workpiece; and
urging positive ions in the steady-state plasma to move from the first zone to the second zone after temporarily inhibiting the positive ions.

43. The method of claim 37, further comprising selectively controlling the position of the positive ions in the steady-state plasma.

44. The method of claim 37, further comprising electrically charging a barrier positioned between a first zone in the second deposition chamber and a second zone in the second deposition chamber.

45. A method for depositing material onto a microfeature workpiece, comprising:
depositing molecules of a first gas onto the microfeature workpiece in a first deposition chamber;
moving the microfeature workpiece from the first deposition chamber to a second deposition chamber spaced apart from the first deposition chamber after depositing the first gas molecules;
generating a plasma in the second deposition chamber;
selectively urging at least a portion of the plasma toward the microfeature workpiece in the second deposition chamber; and
depositing molecules of a second gas onto the microfeature workpiece in the second deposition chamber.

46. The method of claim 45 wherein selectively urging at least a portion of the plasma comprises electrically charging a conductive barrier in the second deposition chamber.

47. The method of claim 45 wherein selectively urging at least a portion of the plasma comprises applying a negative charge to a conductive barrier in the second deposition chamber.

48. The method of claim 45 wherein generating the plasma in the second deposition chamber comprises producing a steady-state plasma in the second deposition chamber.

49. The method of claim 45, further comprising:
positioning the workpiece in the first deposition chamber after depositing molecules of the second gas onto the first gas molecules; and
depositing molecules of the first gas onto the workpiece after positioning the workpiece in the first deposition chamber.

50. The method of claim 45 wherein generating the plasma in the second deposition chamber comprises producing the plasma in a first zone of the second deposition chamber, and wherein the method further comprises temporarily inhibiting positive ions in the plasma from moving from the first zone to a second zone in the second deposition chamber proximate to the workpiece.

51. A method for depositing material onto a microfeature workpiece, comprising:
depositing molecules of a first gas onto the microfeature workpiece in a first deposition chamber;
flowing a second gas into a second deposition chamber spaced apart from the first deposition chamber;
generating a plasma from the second gas in the second deposition chamber while depositing the first gas molecules;
positioning the microfeature workpiece in the second chamber after depositing molecules of the first gas; and
depositing molecules of a third gas onto the microfeature workpiece in the second chamber while generating the plasma in the second chamber.

52. The method of claim 51, further comprising selectively urging at least a portion of the ions in the plasma toward the microfeature workpiece while depositing molecules of the third gas onto the workpiece.

53. The method of claim 51 wherein generating the plasma comprises producing the plasma in a first zone of the second deposition chamber, and wherein the method further comprises temporarily inhibiting positive ions in the plasma from moving from the first zone to a second zone in the second deposition chamber proximate to the workpiece.

54. The method of claim 51 wherein generating the plasma comprises producing the plasma in a first zone of the second deposition chamber, and wherein the method further comprises:
temporarily inhibiting positive ions in the plasma from moving from the first zone to a second zone in the second deposition chamber proximate to the workpiece; and
urging positive ions in the plasma to move from the first zone to the second zone after temporarily inhibiting positive ions.

55. The method of claim 51, further comprising selectively controlling the position of the positive ions in the plasma.

56. The method of claim 51, further comprising electrically charging a barrier positioned between a first zone in the second deposition chamber and a second zone in the second deposition chamber.

57. A method for depositing material onto a microfeature workpiece, comprising:
depositing molecules of a first gas onto the microfeature workpiece in a first deposition chamber;
generating a plasma in a first zone of a second deposition chamber;
electrically charging a barrier to urge at least a portion of the plasma from the first zone toward a second zone in the second deposition chamber adjacent to the microfeature workpiece; and
depositing molecules of a second gas onto the microfeature workpiece in the second deposition chamber.

58. The method of claim 57, further comprising temporarily electrically charging the barrier to inhibit the plasma from moving from the first zone toward the second zone before electrically charging the barrier to urge at least a portion of the plasma from the first zone toward the second zone.

59. The method of claim 57 wherein generating the plasma in the second deposition chamber comprises producing a steady-state plasma in the second deposition chamber.

60. The method of claim 57 wherein depositing molecules of the second gas comprises flowing molecules of the second gas through apertures in the barrier.

61. The method of claim 57 wherein electrically charging the barrier comprises urging at least a portion of the plasma to move through apertures in the barrier.
